(19) United States
(12) Patent Application Publication
(10) Pub. No.: US 2019/0227112 A1
(43) Pub. Date: Jul. 25, 2019

(54) DEVICE, SYSTEM AND METHOD FOR INDICATING AND PREDICTING A STATUS OF AN OUTDOOR OBJECT

(71) Applicant: ATOMATION NET LTD., TEL AVIV (IL)

(72) Inventor: ERAN KESHET, TEL AVIV (IL)

(21) Appl. No.: 16/252,764

(22) Filed: Jan. 21, 2019

Related U.S. Application Data
(60) Provisional application No. 62/619,818, filed on Jan. 21, 2018.

(51) Int. Cl. G01R 31/08

(52) U.S. Cl. CPC G01R 31/085; G01R 31/088

(57) ABSTRACT

A method for monitoring a status of an outdoor object, including storing multiple behavior profiles associated with multiple outdoor objects at a server and/or at the sensor unit itself. Each behavior profile of the multiple behavior profiles is associated with a specific outdoor object of the multiple outdoor objects, establishing a communication channel between the server and multiple sensor units, and or sensor units to other sensor units directly. Each sensor unit is secured to an outdoor object of the multiple outdoor objects and collecting physical measurements at the multiple sensor units. Then, the method includes identifying a significant deviation between the collected physical measurements and a specific behavior profile associated with a specific outdoor object and associating the significant deviation to a series of physical measurements that fit an event.

### FIELD

The invention relates generally to indicating a status of an outdoor object.

### BACKGROUND

A utility pole is a column or post used to support overhead power lines and various other public utilities, such as electrical cable, fiber optic cable, and related equipment such as transformers and street lights. It can be referred to as a transmission pole, telephone pole, telecommunication pole, power pole, hydro pole, telegraph pole, or telegraph post, depending on its application.

Given their importance for the rapid and efficient transfer of public utilities, utility poles demand regular maintenance and replacement. In addition to normal degradation due to age and environmental processes, utility poles are vulnerable to both natural disasters (e.g., storms, hurricanes, earthquakes, fires, etc.), as well as man-made disasters (e.g., car accidents, vandalism, terrorism, etc.). If a utility pole collapses due to wear, weather or an accident, it needs to be replaced immediately, or there will be a disruption in the delivery of certain public utilities.

Knowing which utility pole might need maintenance in the near future or which pole is failing to perform its duty (e.g. power line pole broke in storm and needs to be located etc.) can save money, prevent failure to provide sufficient electric power and increase customers satisfaction.

### SUMMARY

In one embodiment of the invention a method is provided for monitoring a status of an outdoor object, comprising storing multiple behavior profiles associated with multiple outdoor objects at a server, each behavior profile of the multiple behavior profiles is associated with a specific outdoor object of the multiple outdoor objects, establishing a communication channel between the server and multiple sensor units, each sensor unit is secured to an outdoor object of the multiple outdoor objects, collecting physical measurements at the multiple sensor units, identifying a significant deviation between the collected physical measurements and a specific behavior profile associated with a specific outdoor object and associating the significant deviation to a series of physical measurements that fit an event.

In some embodiments of the invention, the method further comprises creating the behavior profile based on time-based correlation between the collected physical measurements of sensors of the specific outdoor object and objective information. In some embodiments of the invention, the multiple outdoor objects are utility poles, and wherein the multiple sensor units are secured to the utility poles.

In some embodiments of the invention, the method further comprises updating the specific behavior profile according to environmental events and changes in the collected measurements that occur during the environmental events. In some embodiments of the invention, the method further comprises sending the updated behavior profile from the server to the sensor unit associated with the specific outdoor object.

In some embodiments of the invention, the method further comprises predicting the event according to match of significant deviations to the series of physical measurements. In some embodiments of the invention, the method further comprises sending a signal identifying the predicted event to a central system.

In some embodiments of the invention, the multiple outdoor objects are utility poles, further comprises detecting loss of power in a specific region according to actual electric power measurements by a sensor attached to the utility pole, according to the physical measurements and according to additional data received at the server and identifying utility poles closer to a location of loss of power according to deviation in physical measurements from the multiple sensors installed on different utility poles in the specific region.

In some embodiments of the invention, the method further comprises storing each behavior profile of the multiple behavior profiles on a sensor unit associated with the specific outdoor object.

In another embodiment of the invention a system is provided for monitoring a status of an outdoor object, comprising multiple sensor units installed on multiple outdoor objects, a central server communicating with the multiple sensor units, wherein the multiple sensor units and the central server are configured to execute a set of instructions, said set of instructions comprises storing multiple behavior profiles associated with multiple outdoor objects at a server, each behavior profile of the multiple behavior profiles is associated with a specific outdoor object of the multiple outdoor objects, establishing a communication channel between the server and multiple sensor units, each sensor unit is secured to an outdoor object of the multiple outdoor objects, collecting physical measurements at the multiple sensor units, identifying a significant deviation between the collected physical measurements and a specific behavior profile associated with a specific outdoor object and associating the significant deviation to a series of physical measurements that fit an event.

### BRIEF DESCRIPTION OF THE DRAWINGS

Some embodiments of the invention are herein described, by way of example only, with reference to the accompanying drawings. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIG. 1 shows multiple utility poles connected via a network to a central server, according to exemplary embodiments of the invention;

FIGS. 2A-2B show multiple utility poles mounted near a roadway, according to exemplary embodiments of the invention;

FIG. 3 shows a sensor unit secured to a utility pole, according to exemplary embodiments of the invention;

FIG. 4 shows a method of predicting events or positions of a utility pole, according to exemplary embodiments of the invention;

FIG. 5 shows a method of updating a behavior profile of an outdoor object such as a utility pole, according to exemplary embodiments of the invention; and,

FIG. 6 shows a method of locating a utility pole close to a location of an event that caused reduction of electrical power, according to exemplary embodiments of the invention.

### DETAILED DESCRIPTION

The invention in embodiments thereof discloses a method of analysis and predicting behavior of outdoor objects. The behavior may refer to events that occur to or in the outdoor objects, may be derived from such events, may be derived from such events combined with other data sources such as temperature, humidity data received from another sensor or sensor unit or information obtained from another source such as the internet etc. The events may be failure of the outdoor objects, physical collapse, movement of the outdoor objects, other objects hitting the outdoor objects and the like. The analysis or prediction of an event is based on a profile of the outdoor object, collecting physical information of the outdoor object using a sensor unit or units located on the outdoor object or in its proximity, creating a behavioral profile of the outdoor object according to the measurements taken by the sensor unit, and analyzing changes between the collected measurements and the behavior profile. When the change is determined to be of significance, for example exceeding a predefined threshold relative to the behavior profile, the sensor unit generates a signal indicating that an event associated with the changes from the behavior profile is likely to occur and send the signal to a remote unit that holds data on the plurality of outdoor objects. The sensor unit may either only send the measurements, and the remote unit will associate the measurements to a conclusion or conduct calculation locally (also known as edge computing) and send a signal with the conclusions by itself.

The outdoor object may be an outdoor facility, for example infrastructure element such as utility poles, bridges' infrastructure, greenhouses, roads, ports, and the like. The sensor unit may comprise at least one sensor selected from of an accelerometer, a gyroscope, a camera, temperature sensor, humidity sensor, wind speed, wind direction, compass, electromotive force (EMF), sound sensor, a clock and the like. The sensor unit may be located within a housing, configured to enable the sensor unit to operate for a long period of time, in the range of 1 year and more. The housing may be secured to the outdoor object, or to a platform near the outdoor object. For example, the housing may be designed to be secured to a specific section of utility poles, in the height in the range of 5-7 meters. In some exemplary embodiments of the invention, a system is provided having multiple sensor units secured to the same outdoor object type, for example utility poles, bridges' infrastructure, greenhouses and the like, and a central server communicating with the multiple sensor units, generating signals to other units or to a dedicated server that may reside on the internet or to a cellular network or to a mobile device in possession of a person or attached to vehicle etc. to solve technical problems of the outdoor objects before they happen, or when they are about to happen or after they happened (in a situation where the event was not predicted such as car hitting the outdoor object etc.).

In some cases, a prediction or after the fact knowledge of a collapsed outdoor object can assist in determining which on-site unit should go to each outdoor object in order to optimize the accumulate failure time of all utility poles in a specific region. In such a case, the central server can access the location information of the utility poles and the number of persons or houses exposed to lack of electricity or other services. For example, the central server may determine that 3 poles are about to collapse—one within 12 minutes, another within 25 minutes and the third within 45 minutes. The central server has the current location of the on-site units, and the regions which are affected by collapse of each pole. The central server may compute a function which receives the location of the poles and the regions they serve. The output of the function may be prioritizing the importance of the poles. For example, the central server may send a first unit to the third pole, even in case the first unit is closer to the second pole, as the third pole serves a larger population. The sensor unit comprises a memory module for storing the outdoor object's general profile, behavior profile, prior measurements and the like.

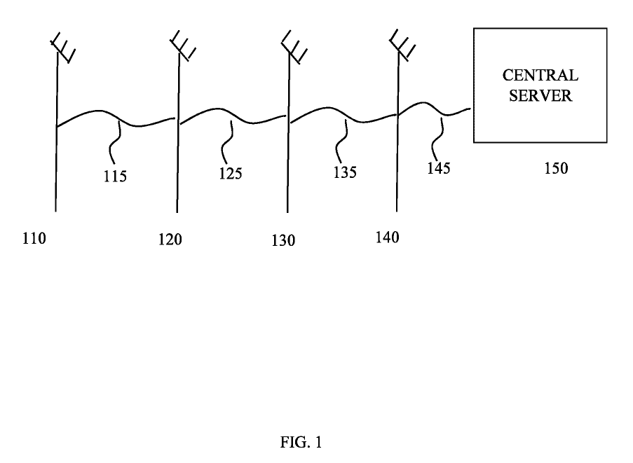

FIG. 1 shows multiple utility poles connected via a network to a central server, according to exemplary embodiments of the invention. The multiple utility poles 110, 120, 130, 140 may be located in the same region, for example within 10-1000 meters from each other. The multiple utility poles 110, 120, 130, 140 are assumed to have substantially the same climate over time. The multiple utility poles 110, 120, 130, 140 comprise sensor units and preferably housings for securing the sensor units to the poles. Data sent from senor units of the invention is sent from the multiple utility poles 110, 120, 130, and 140 to a central server 150 via a network, for example via communication between the units themselves in ways such as meshed networking, via the internet, via a cellular network and the like. In some cases, the data is sent over the electricity network 115, 125, 135 and 145, for example by signaling the signals or messages generated by communication modules installed in the sensor units.

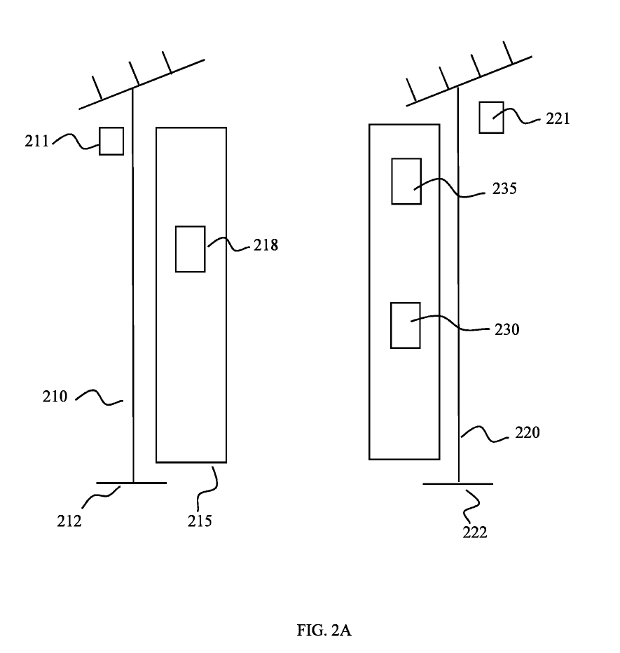

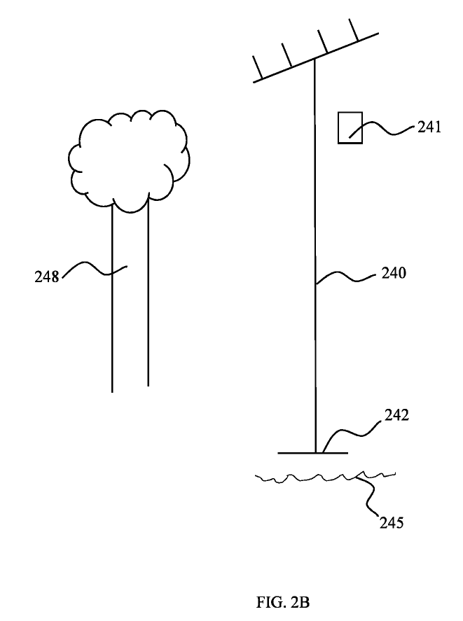

FIGS. 2A-2B show multiple utility poles mounted near a roadway, according to exemplary embodiments of the invention. Each of the outdoor objects, such as utility poles, that use the sensor unit and the methods of the invention, has a specific profile. The profile comprises specific environmental information about the outdoor object, as well as behavioral profile, which represents the measurements taken by a sensor unit of a specific outdoor object according to a set of conditions. For example, one outdoor object may react differently to the same set of conditions than another outdoor object, even when the physical properties of both outdoor objects are the same. This way, each outdoor object has its own behavioral profile.

FIG. 2A shows two utility poles 210 and 220 positioned on both sides of a roadway 215. One vehicle 218 rides on the lane closer to pole 210 and two vehicles 230, 235 ride on the lane closer to the pole 220. Both poles 210 and 220 are of substantially the same properties and were manufactured identically. Pole 210 comprises sensor unit 211, installed on basis 212. Pole 220 comprises sensor unit 221, installed on basis 222. Even when the bases 212 and 222 are identical, for example made of the same size of concrete, the poles may behave differently to the same set of conditions. For example, due to the fact that pole 210 is closer to a valley or to the ocean, which dictates different wind sensitivity by pole 210, which is less felt by pole 220. Thus, sensor units 211, 221 may measure the same properties besides wind speed, and have different Inertial Measurement Units (IMUs) measurements. The IMUs may combine accelerometer and gyroscope measurements and may function as the movement sensor in the sensor unit. The IMU measurements may be sent to the central server 150 of FIG. 1 or be processed to trigger an event locally on the pole's sensor unit. The standard IMU measurements of the pole 210, which is closer to the ocean may be higher than the standard IMU measurements of pole 220. This way, irregular measurement of the pole 220 may be considered regular when measured by the pole 210. The concrete basis of both poles may be inputted by the person installing the sensor units 211 and 221, as part of the poles' profile.

FIG. 2B shows a utility pole 240 located near a forest 248. Sensor unit 241 is attached to Pole 240. The pole 240 is mounted on a base 242, which resides on sand 245. This way, when rain pours near the pole 240, the sand 245 becomes mud and the base 242 is less stable. Then, the measurements taken by the same wind change due to the rain are different from the same wind speed without rain.

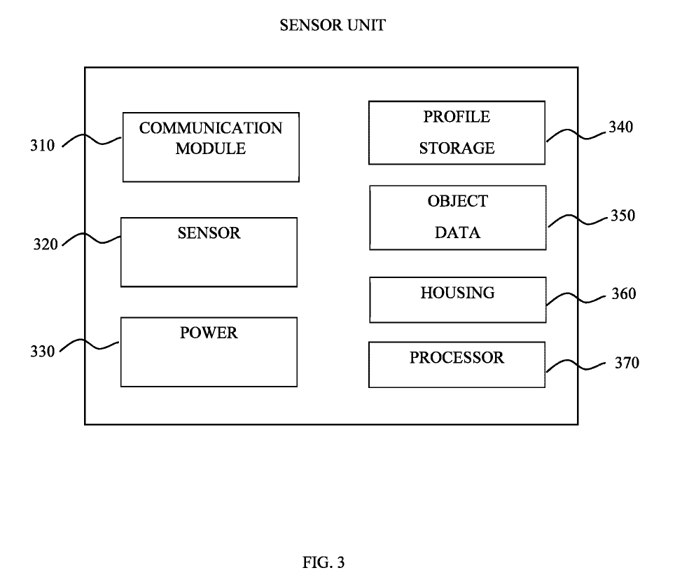

FIG. 3 shows a sensor unit secured to a utility pole, according to exemplary embodiments of the invention. The sensor unit comprises a sensor 320 configured to collect measurements associated with the pole. The sensor 320 may a plurality of sensors. One of the sensors may reflect the movements of the outdoor object, for example an accelerometer or gyroscope. The sensor 320 may comprise an environmental sensor configured to measure properties in the vicinity of the outdoor object, for example climate-based measurements such as temperature, humidity, rain and the like. The sensor 320 may detect noise and identify construction work performed near the object. Such construction may be part of the outdoor object's profile.

The sensor unit also comprises a communication module 310 configured to transmit signals according to measurements of the sensor 320. In some cases, the communication module 310 sends signals determined by a processor 370 contained in the sensor unit. The processor 370 analyzes the measurements of the sensor 320 and determines whether or not to send a signal outwards, for example to the central server. The communication module 310 may comprise an internal gateway. The communication module 310 may send signals wirelessly to the communication module of the next outdoor object, for example 20 meters away, using Bluetooth low energy technology or any other technique desired by the person skilled in the art. The communication module 310 may also receive signals, for example from the communication module of the neighboring outdoor object. The communication module 310 may receive signals from an on-site unit, for example software updates to be stored in a memory of the sensor unit.

The sensor unit also comprises a power unit 330 configured to supply power to the components of the sensor unit, for example to the sensor 320, memory, no processor or 1 or multiple processors 370 and communication module 310. The power unit 330 may be a battery. The power unit 330 may be electrically coupled to the utility pole, via a mechanism to adjust the pole power to the low power required by the sensor unit. In some cases, the power unit may comprise renewable energy source, for example a solar panel installed in the pole or in the sensor unit, wind, or other means of energy harvesting.

The sensor unit also comprises a housing 360 configured to enable securing the sensor unit to the outdoor object. The housing 360 may be made of a rigid or semi rigid material, for example metal or plastics, configured to electrically isolate the components of the sensor unit from rain, humidity and the like. The housing 360 may comprise a mechanism such as screws or holes for screws to be installed on the outdoor object, wires for surrounding the outdoor object or tying the housing 360 on or around the outdoor object.

The sensor unit also comprises a memory module. The memory may be volatile or non-volatile. The memory comprises profile data 340 of the outdoor object. Profile data comprises the outdoor object's location, outdoor object's basis type, outdoor object's location, outdoor object size, height of the sensor unit on the outdoor object and the like. The memory module also stores prior sensor measurements 350. The memory module also stores a set of rules used by the processor 370 when determining irregularities in the outdoor object's functioning. The processor 370 and software may also be configured to predict such irregularities according to the set of rules. Such set of rules may be based on software, hardware installed in the sensor unit and accessed by the processor 370.

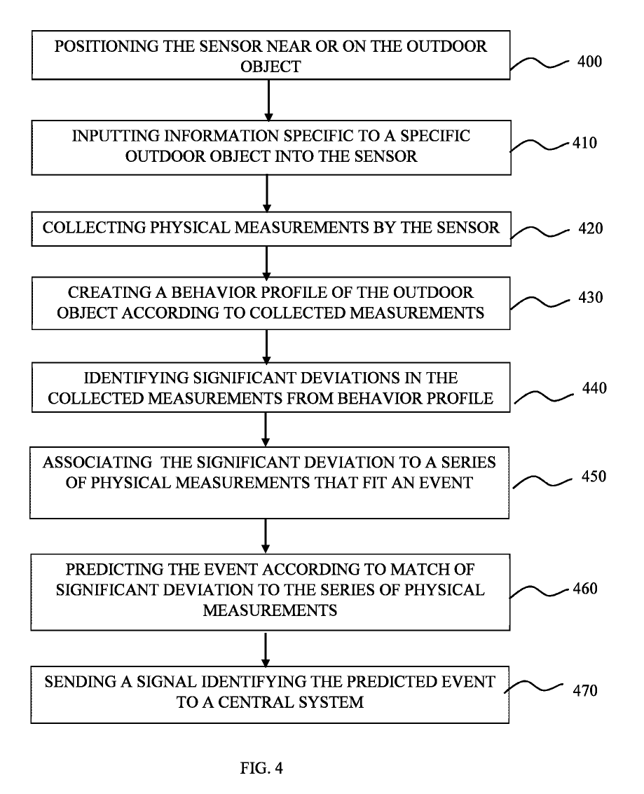

FIG. 4 shows a method of predicting events or positions of a utility pole, according to exemplary embodiments of the invention.

Step 400 discloses positioning the sensor unit near or on the pole. The sensor unit may comprise a housing configured to be secured to the pole, for example using adhesive or screws, or any other mechanism, or using cables surrounding at least a portion of the pole, or attached to the cables that pole holds such as the electric cables themselves.

Step 410 discloses inputting information into the sensor—data about the pole, environment of the pole (sole type for example). Such input may be performed via an input unit of an electronic device communicating with the communication module of the sensor unit, for example via an installer's device or tablet or smartphone, located near the communication module or via another sensor unit which communicates with the sensor unit, or via an update to the central server which will update the sensor unit. Such input of information may be performed when installing the sensor unit or when required, for example when moving the sensor unit, or according to seasonal or environmental changes either using a wired connection or via a wireless connection.

Step 420 discloses collecting physical measurements by the sensor. The sensor may reside inside the sensor unit or outside of it, connected to it via a wired or a wireless connection. Sensor data may arrive to the sensor unit also from other remote units or from the central server (e.g. the central server may send data regarding events such as an approaching storm or other conditions that may be detected or identified by means other than the unit's sensors). The physical measurements may represent movements of the pole, or environmental information such as weather, sound, images and the like. The physical measurements may represent forces measured, such as by an accelerometer, electricity flow such as EMF sensor etc.

Step 430 discloses creating a behavior profile of the pole according to collected measurements. The behavior profile comprises measurements of certain sensors of the pole (such as IMU, sound etc.) correlated with objective information measured by additional sensors. Such objective information may be wind, rain, time in the day and the like or other data that the sensor unit received which may be relevant to the measurements taken by the sensor unit. Creation of the behavior profile is based on time-based correlation of the objective information and the collected physical measurements.

The behavior profile is specific to each pole, as some poles react differently to the same weather. For example, the same physical measurement, such as movement, may be defined as a significant deviation from a behavior profile in one pole but may be within normal behavior for another pole. The pole's behavioral profile is stored in the sensor unit memory. The behavioral profile may be stored in the central server and or in other sensor units. The pole's behavioral profile may be determined according to a predefined set of rules implemented by software, and/or hardware, which receives as input the collected measurements and/or data from other sources. The set of rules dictates the values which define normal behavior of the pole in various situations, such as various weather conditions. The specific pole's behavior profile may be dynamically updated. The update may be determined by the sensor unit or by the central server, according to a predefined set of rules that receive as input the physical measurements and/or information received at the central server.

Step 440 discloses identifying significant deviations from behavior profile of a specific outdoor object, such as a utility pole. The deviation may be identified by the sensor unit or by the central server. Such deviation may be determined for example when the movement values (for example by the gyro and accelerometer) measured by the sensor of the sensor unit are not within certain thresholds or desired values of readings. The significant deviations correlate objective measurements, such as weather conditions, with the physical measurements. For example, according to a specific behavior profile of a specific outdoor object, movement of 2.5-4 centimeters is defined within normal range. When detecting movement of more than 4 centimeters, such movement is defined as a significant deviation from the specific behavior profile of the specific outdoor object.

Identifying significant deviation from the behavior profile may be performed locally on the specific outdoor object or on the central server. The significant deviation may be interpreted as various events according to identified behavior. The various events may include failure in pole structure, alert that maintenance is needed, detect impact on pole or on cables, detect structure failure, detect fallen pole, determine location of an issue such as torn cables between poles in accordance to data correlation and the like.

Step 450 discloses associating significant deviations to a series of physical measurements that fit an event. Such event may be failure of the pole, the pole falling, another object hitting the pole, change in the pole's position versus the ground and the like. The events and characteristics of the events may be stored in both the sensor unit and the central server. The series of physical measurements may be collected during a period of time, for example within 2-900 seconds. If the series of movement measurements accelerate in a specific level, such acceleration may match a predefined event, or a probability of an event. For example, acceleration at a first value A1 may define probability P1 for the pole to fall down, while acceleration A2 (for example 0.2 m/s2) may define probability P2 for the pole to fall down, as P2 may be different from P1.

Step 460 discloses predicting the event according to match of significant deviations to a series of physical measurements. Prediction is performed in the processor according to the predefined set of rules and a statistical model stored in the memory unit of the sensor unit or in the central server. In some exemplary cases, the sensor unit may not have a processor and the method disclosed in the subject matter may be performed using hardware configurations resulting from the collected physical measurements in order to determine the actions and or conclusions disclosed herein. Step 470 discloses sending a signal to the central system that the event is predicted. Such sending may be made over the electricity network, BLE, wireless network or by any other means of communication. Either directly to the server, through a gateway or via communication with other unit nodes.

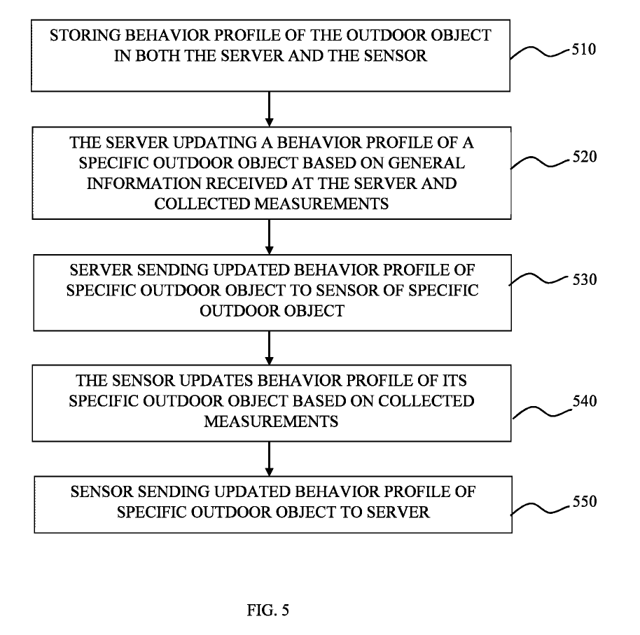

FIG. 5 shows a method of updating a behavior profile of an outdoor object such as a utility pole, according to exemplary embodiments of the invention.

Step 510 discloses storing a behavior profile of the specific outdoor object in both the central server and the sensor unit of the specific outdoor object. The behavior profile comprises values indicating normal behavior of the specific outdoor object in various conditions. The normal behavior may comprise movements of the specific outdoor object or other properties that may be collected by the sensor unit.

Step 520 discloses the server updating the behavior profile of the specific outdoor object based on general information received at the server and collected physical measurements. For example, the specific outdoor object's stability may deteriorate gradually, and the behavior profile will match such deterioration. For example, normal behavior of the specific outdoor object may be in the movement range of 1.5-4 centimeters, and will be updated to 1.5-4.2 after collecting the appropriate measurements. This way, measurement of 4.1 will not be considered significant deviation, but will be used to update the specific behavior profile.

Step 530 discloses server sending the updated behavior profile of the specific outdoor object to sensor. Such sensing may be via the internet, via a physical channel secured to an electrical grid and the like.

Step 540 discloses the sensor unit updating the behavior profile of its specific outdoor object based on collected measurements and objective information. In such embodiment, the sensor unit comprises a memory having a set of predefined rules. The predefined rule dictate how to update the behavior profile. The predefined rules determine whether the collected physical measurements dictate updating the behavior profile or dictate predicting an event, such as collapse of the specific outdoor object.

Step 550 discloses sensor sending updated behavior profile of specific outdoor object to the central server. Such sending may be equivalent to step 530.

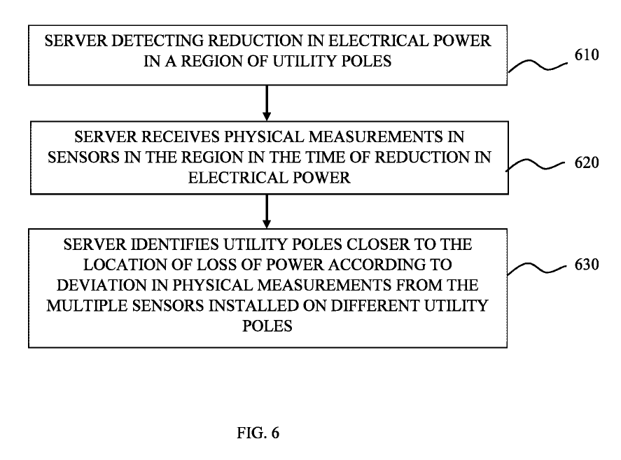

FIG. 6 shows a method of locating a utility pole close to a location of an event that caused reduction of electrical power, according to exemplary embodiments of the invention.

Step 610 discloses server detecting reduction in electrical power in a region of utility poles. Reduction in the electrical power may comprise loss of power due to collapse of a utility pole, or due to an object hitting an electricity cable set between two utility poles. When such loss of power occurs, the central server detects changes in power at other utility poles and the central server obtains the time in which the loss of power occurred, as well as a region in which the loss of power occurred.

Step 620 discloses server receives physical measurements in sensors in the region in the time of reduction in electrical power. The central server may define which utility poles are included in the region in which the loss of power occurred. Such definition may be automated according to a known location of each of the utility poles, correlated with the location of the loss of power. The central server receives the physical measurements periodically, for example once every 2 minutes, or in response to a predefined event. Such event may be the sensor unit in the utility poles identifying abnormality in the collected physical measurements, or significant deviation from the behavior profile of the specific utility pole.

Step 630 discloses the central server identifies utility poles closer to the location of loss of power according to deviation in physical measurements from the multiple sensors installed on different utility poles. The deviations may be identified locally, at the server units, or at the central server. It is likely that the deviations from the behavior profile indicate an event, such as collapse of a utility pole associated with the significant deviation, or a utility pole near the sensor unit associated with the significant deviation. This way, identifying the significant deviation enables power companies to locate the source of loss of energy when the loss of energy occurs due to a physical failure, such as collapse of a utility pole or an object hitting the utility pole. The power company can send technical personnel to the specific utility pole to be fixed, instead of sending the personnel to a region having 1000 poles, thus resuming power much faster with reduced labor costs.

While the disclosure has been described with reference to exemplary embodiments, it will be understood by those skilled in the art that various changes may be made, and equivalents may be substituted for elements thereof without departing from the scope of the invention. In addition, many modifications may be made to adapt a particular situation or material to the teachings without departing from the essential scope thereof. Therefore, it is intended that the disclosed subject matter not be limited to the particular embodiment disclosed as the best mode contemplated for carrying out this invention, but only by the claims that follow.

What is claimed is:

1. A method for monitoring a status of an outdoor object, comprising:
storing multiple behavior profiles associated with multiple outdoor objects at a server, each behavior profile of the multiple behavior profiles is associated with a specific outdoor object of the multiple outdoor objects;
establishing a communication channel between the server and multiple sensor units, each sensor unit is secured to an outdoor object of the multiple outdoor objects;
collecting physical measurements at the multiple sensor units;
identifying a significant deviation between the collected physical measurements and a specific behavior profile associated with a specific outdoor object;
associating the significant deviation to a series of physical measurements that fit an event.

2. The method according to claim 1, further comprising creating the behavior profile based on time-based correlation between the collected physical measurements of sensors of the specific outdoor object and objective information.

3. The method according to claim 1, wherein the multiple outdoor objects are utility poles, and wherein the multiple sensor units are secured to the utility poles.

4. The method according to claim 1, further comprising updating the specific behavior profile according to environmental events and changes in the collected measurements that occur during the environmental events.

5. The method according to claim 4, further comprising sending the updated behavior profile from the server to the sensor unit associated with the specific outdoor object.

6. The method according to claim 1, further comprising predicting the event according to match of significant deviations to the series of physical measurements

7. The method according to claim 6, further comprising sending a signal identifying the predicted event to a central system.

8. The method according to claim 1, wherein the multiple outdoor objects are utility poles, further comprising:
detecting loss of power in a specific region according to actual electric power measurements by a sensor attached to the utility pole, according to the physical measurements and according to additional data received at the server;
identifying utility poles closer to a location of loss of power according to deviation in physical measurements from the multiple sensors installed on different utility poles in the specific region.

9. The method according to claim 1, further comprising storing each behavior profile of the multiple behavior profiles on a sensor unit associated with the specific outdoor object.

10. A system for monitoring a status of an outdoor object, comprising:
multiple sensor units installed on multiple outdoor objects;
a central server communicating with the multiple sensor units;
wherein the multiple sensor units and the central server are configured to execute a set of instructions, said set of instructions comprises:
storing multiple behavior profiles associated with multiple outdoor objects at a server, each behavior profile of the multiple behavior profiles is associated with a specific outdoor object of the multiple outdoor objects;
establishing a communication channel between the server and multiple sensor units, each sensor unit is secured to an outdoor object of the multiple outdoor objects;
collecting physical measurements at the multiple sensor units;
identifying a significant deviation between the collected physical measurements and a specific behavior profile associated with a specific outdoor object;
associating the significant deviation to a series of physical measurements that fit an event.
